(19) United States
(12) Patent Application Publication
(10) Pub. No.: US 2019/0360087 A1
(43) Pub. Date: Nov. 28, 2019

(54) METHOD FOR MANUFACTURING VAPOR DEPOSITION MASK

(71) Applicant: Sharp Kabushiki Kaisha, Sakai City, Osaka (JP)

(72) Inventor: Shinichi ESUMI, Sakai City (JP)

(21) Appl. No.: 16/477,561

(22) PCT Filed: Aug. 22, 2017
(86) PCT No.: PCT/JP2017/029950

§ 371 Date: Jul. 12, 2019

(51) Int. Cl. C23C 14/04

(52) U.S. Cl. CPC C23C 14/042; H01L 51/0011

(57) ABSTRACT

Provided is a method for manufacturing a vapor deposition mask including a frame including a first side member and a second side member that extend in a first direction; and one or more mask sheets, the method including: stretching the one or more mask sheets on the first side member and the second side member in a state where an outside of the first side member is pressed in a direction from the first side member toward the second side member and where an outside of the second side member is pressed in a direction from the second side member toward the first side member.

### TECHNICAL FIELD

The disclosure relates to a method for manufacturing a vapor deposition mask and the like.

### BACKGROUND ART

PTL 1 discloses a method for stretching a mask sheet on a frame while pulling it outwards so as not to cause wrinkles or the like.

### CITATION LIST

### Patent Literature

PTL 1: JP 2015-28204 A (published on Feb. 12, 2015)

### SUMMARY

### Technical Problem

In a case that the mask sheet is stretched on the frame while being pulled outwards, there is a problem in that the frame is deformed due to the tension of the mask sheet.

### Solution to Problem

A method for manufacturing a vapor deposition mask according to one aspect of the disclosure provides a method for manufacturing a vapor deposition mask including a frame including a first side member and a second side member that extend in a first direction; and one or more mask sheets, the method including stretching the one or more mask sheets on the first side member and the second side member in a state where an outside of the first side member is pressed in a direction from the first side member toward the second side member and where an outside of the second side member is pressed in a direction from the second side member toward the first side member.

### Advantageous Effects of Disclosure

It is possible to prevent the frame from being deformed due to the tension of the mask sheet.

### BRIEF DESCRIPTION OF DRAWINGS

FIG. 1 is a flowchart illustrating an example of a method for manufacturing a display device.

FIG. 2 is a cross-sectional view illustrating a configuration example of a displaying unit of a display device.

FIG. 3 is a schematic view illustrating a vapor deposition method used to form a light-emitting element layer.

FIG. 4 is a flowchart illustrating a method for manufacturing a vapor deposition mask according to a first embodiment.

FIG. 5 is a plan view illustrating a vapor deposition mask used in the first embodiment.

FIG. 6 is a block diagram illustrating a manufacturing apparatus for a vapor deposition mask according to the first embodiment.

FIG. 7A is a plan view, FIG. 7B is a cross-sectional view, and FIG. 7C is a side view, each illustrating a pressing step according to the first embodiment.

FIG. 8 is a flowchart illustrating a method for manufacturing a vapor deposition mask according to a second embodiment.

FIG. 9A is a plan view, FIG. 9B is a cross-sectional view, and FIG. 9C is a side view, each illustrating a pressing mechanism according to the second embodiment.

### DESCRIPTION OF EMBODIMENTS

Hereinafter, the “same layer” means that the same material is used to form the layer in the same process. The “lower layer” means that the layer is formed in a process performed before a layer to be compared is formed. The “upper layer” means that the layer is formed in a process performed after a layer to be compared is formed.

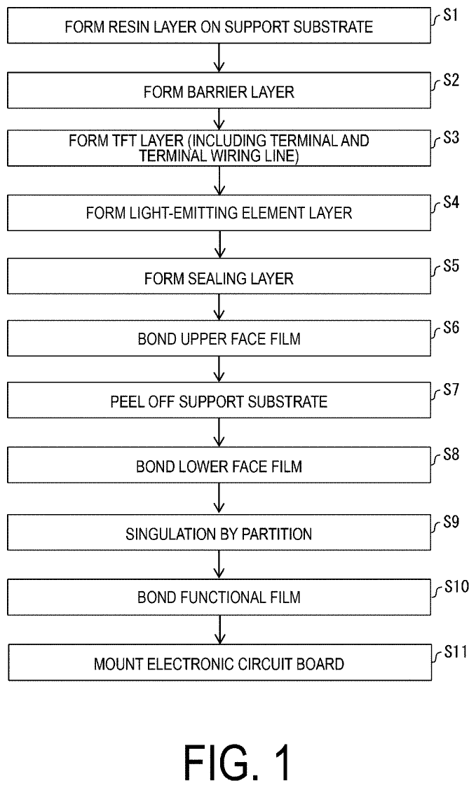

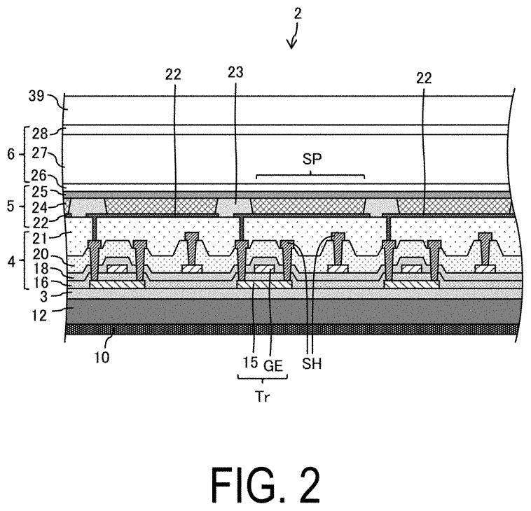

FIG. 1 is a flowchart illustrating an example of a method for manufacturing a display device. FIG. 2 is a cross-sectional view illustrating a configuration example of a displaying unit of the display device. In a case of manufacturing a flexible display device, a resin layer 12 is first formed on a support substrate (for example, a mother glass substrate) as illustrated in FIG. 1 and FIG. 2 (step S1). Next, a barrier layer 3 is formed (Step S2). Next, a TFT layer 4 is formed (step S3). Next, a light-emitting element layer 5 is formed (step S4). Next, a sealing layer 6 is formed (step S5). Next, an upper face film is bonded on the sealing layer 6 (step S6). Next, the support substrate is peeled from the resin layer 12 (step S7). Next, a lower face film 10 is bonded on the lower face of the resin layer 12 (step S8). Next, the layered body obtained through steps S1 to S8 is partitioned to obtain plural individual pieces (step S9). Next, a functional film 39 is bonded on the obtained individual pieces (step S10). Next, electronic circuit boards (for example, IC chips) are mounted on the terminal portion to form a display device 2 (step S11). Note that each of the above-described steps is performed by using a display device manufacturing apparatus that will be described later.

The lower face film 10 (for example, PET) and the resin layer 12 (for example, polyimide) function as a flexible base material. The barrier layer 3 (for example, silicon nitride or silicon oxide) functions to prevent foreign substances such as moisture and oxygen from entering the TFT layer 4 and the light-emitting element layer 5.

The TFT layer 4 includes a semiconductor film 15 (for example, LTPS or oxide semiconductor), an inorganic insulating film 16 (for example, silicon nitride or silicon oxide) that is an upper layer than the semiconductor film 15, a gate electrode GE that is an upper layer than the inorganic insulating film 16, inorganic insulating films 18 and 20 (for example, silicon nitride or silicon oxide) that are upper layers than the gate electrode GE, a source wiring line SH that is an upper layer than the inorganic insulating film 20, and a flattering film 21 (for example, polyimide) that is an upper layer than the source wiring line SH. A thin film transistor (TFT) Tr is configured so as to include the semiconductor film 15, the inorganic insulating film 16, and the gate electrode GE.

The light-emitting element layer 5 includes an anode 22 (for example, Ag alloy) that is an upper layer than the flattering film 21, a bank 23 (for example, polyimide) that covers an edge of the anode 22, an electroluminescence (EL) layer 24 that is an upper layer than the anode 22, and a cathode 25 (for example, ITO) that is an upper layer than the EL layer 24. A light emitting element (for example, organic light emitting diode: OLED) including the anode 22 in an island-shape, the EL layer 24, and the cathode 25 is formed for each subpixel defined by the bank 23. The EL layer 24 is formed, for example, by layering a hole injection layer, a hole transport layer, a light-emitting layer, an electron transport layer, and an electron injection layer in this order with the hole injection layer being the bottom layer. The light-emitting layer is formed in an island shape for each subpixel by using vapor deposition method. At least one of the hole injection layer, the hole transport layer, the electron transport layer, or the electron injection layer may be a solid-like common layer or may be omitted (not formed).

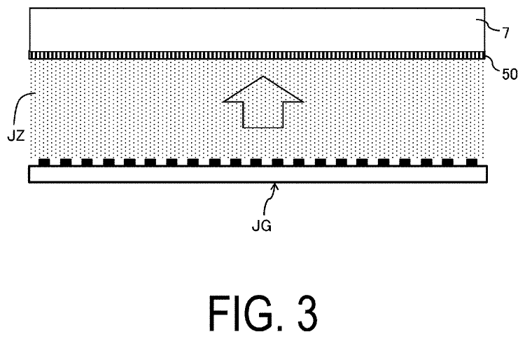

FIG. 3 is a schematic view illustrating a vapor deposition method used to form a light-emitting element layer. As illustrated in FIG. 3, in a vapor deposition method, a vapor deposition mask 50 (which will be described below) including through-holes corresponding to subpixels is disposed below a layered body 7 including a support substrate, a resin layer, a barrier layer, a TFT layer, an anode, and a bank (anode edge cover). This allows a vapor deposition material JZ (for example, a material of the light-emitting layer), emitted from a vapor deposition source JG, that passes through the through-holes, to be deposited in the bank.

In the case where the light-emitting element layer 5 is an OLED layer, positive holes and electrons are recombined inside the EL layer 24 by a drive current between the anode 22 and the cathode 25. This generates excitons. The excitons fall into a ground state to emit light. Since the anode 22 has light reflectivity and the cathode 25 has light transparency, the light emitted from the EL layer 24 travels upwards and results in top emission. The configuration of the light-emitting element layer 5 is not limited to an OLED and may be an inorganic light emitting diode or a quantum dot light emitting diode.

The sealing layer 6 includes a first inorganic sealing film 26 that covers the cathode 25, an organic sealing film 27 that is formed in an upper layer than the first inorganic sealing film 26, and a second inorganic sealing film 28 that covers the organic sealing film 27, and the sealing layer 6 has a function for preventing foreign substances such as water and oxygen from penetrating into the light-emitting element layer 5. The functional film 39 includes, for example, an optical compensation function, a touch sensor function, a protection function, or the like.

Descriptions have been made of a case of manufacturing the flexible display device. In the case of manufacturing a non-flexible display device, replacement of the substrate and the like is not required, and hence the process may advance from step S5 to step S9 illustrated in FIG. 1, for example.

### First Embodiment

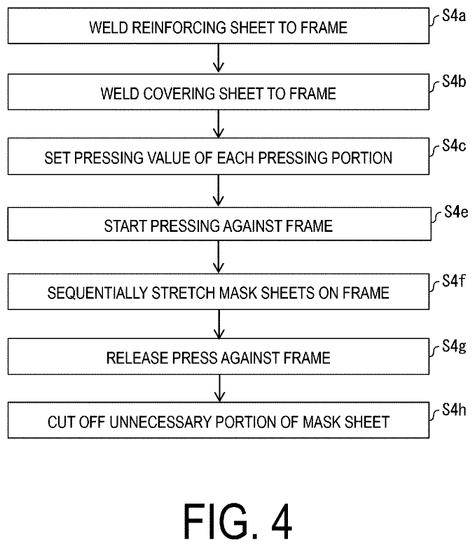

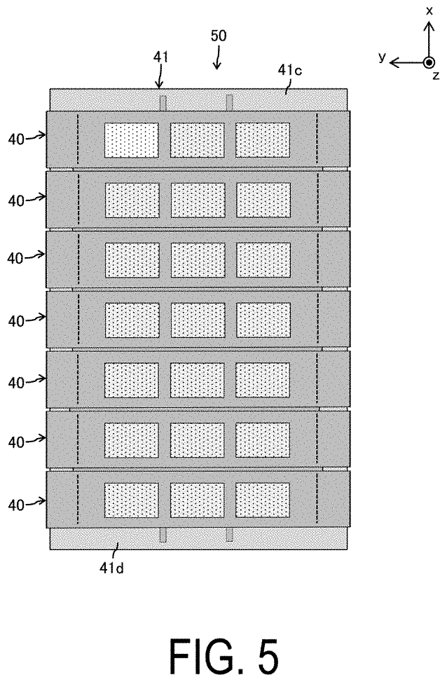

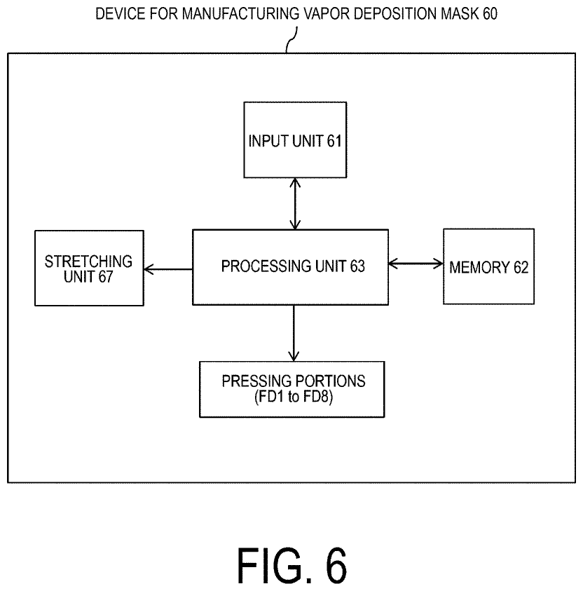

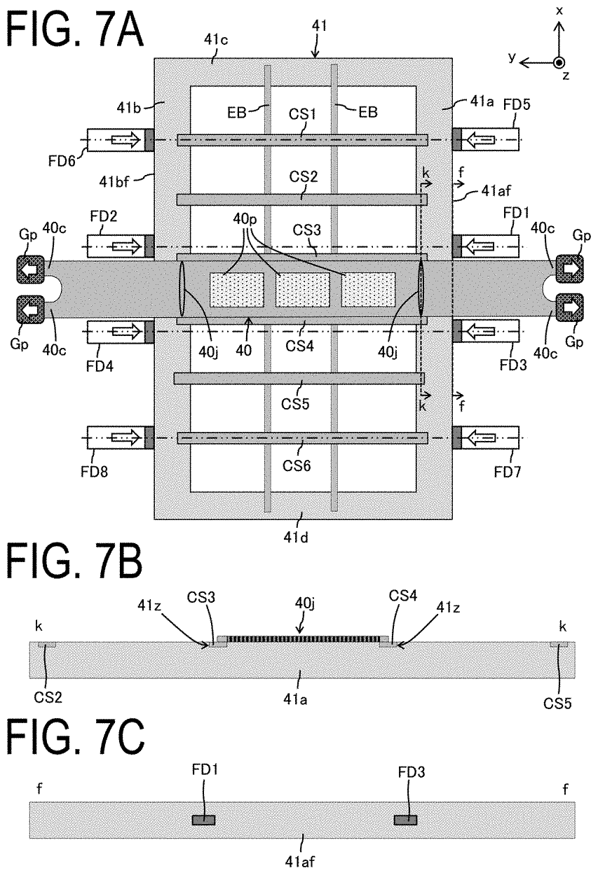

FIG. 4 is a flowchart illustrating a method for manufacturing a vapor deposition mask according to the first embodiment. FIG. 5 is a plan view illustrating a vapor deposition mask. FIG. 6 is a block diagram illustrating a device configured to manufacture a vapor deposition mask according to the first embodiment. FIG. 7A is a plan view, FIG. 7B is a cross-sectional view taken along k-k, and FIG. 7C is a side view along f-f, each illustrating a pressing step according to the first embodiment.

Step S4 in FIG. 1 includes steps (S4a to S4h) for manufacturing a vapor deposition mask illustrated in FIG. 4. In the first embodiment, a device (FIG. 6) for manufacturing a vapor deposition mask is used to manufacture a vapor deposition mask (FIG. 5). As illustrated in FIG. 5 and FIG. 6, the vapor deposition mask 50 includes a frame 41, and mask sheets 40 (also called an elongated mask or divided mask) that are stretched on the frame. A device for manufacturing a vapor deposition mask 60 includes an input unit 61, a memory 62, a processing unit 63, a stretching unit 67, and pressing portions FD1 to FD8.

In step S4a in FIG. 4, reinforcing sheets EB are welded to the frame 41 as illustrated in FIGS. 7A to 7C. The frame 41 includes a first side member 41a and a second side member 41b each extending in a direction x (first direction) and also includes a third side member 41c and a fourth side member 41d each extending in a direction y (second direction). The direction x (the longitudinal direction of the frame) and the direction y are perpendicular to each other. Each of the reinforcing sheets EB is a strip-shaped member elongated in the direction x. The sheet is welded in a state where both ends thereof are fitted into a groove formed in the third side member 41c and the fourth side member 41d.

In step S4b, covering sheets CS1 to CS6 for covering gaps between the mask sheets are welded to the frame 41 as illustrated in FIGS. 7A to 7C. Each of the covering sheets (CS1 to CS6) is a strip-shaped member elongated in the direction y. The sheet is welded in a state where both ends thereof are fitted into a groove 41z formed in the first side member 41a and the second side member 41b. The covering sheets CS1 to CS6 are arranged in the direction x in this order from the third side member 41c side. The upper faces of the covering sheets are flush with the upper faces of the first side member 41a and the second side member 41b (see FIG. 7B).

In step S4c, pressing values for the pressing portions FD1 to FD8 are set. More specifically, in the device for manufacturing a vapor deposition mask 60 in FIG. 6, an operator inputs pressing values for the pressing portions FD1 to FD8 through the input unit 61, and the processing unit 63 writes the pressing values in the memory 62.

In step S4e, pressing the frame 41 starts. The pressing portion FD5, the pressing portion FD1, the pressing portion FD3, and the pressing portion FD7 are arranged, outside the first side member 41a, in the direction x in this order from the third side member 41c side as illustrated in FIGS. 7A to 7C. The pressing portion FD5, the pressing portion FD1, the pressing portion FD3, and the pressing portion FD7, controlled by the processing unit 63, each press an outside surface 41af of the first side member 41a in a direction from the first side member 41a toward the second side member 41b (the left direction in the drawing) by using the pressing values set in step S4c.

Furthermore, the pressing portion FD6, the pressing portion FD2, the pressing portion FD4, and the pressing portion FD8 are arranged, outside the second side member 41b, in the direction x in this order from the third side member 41c side. The pressing portion FD6, the pressing portion FD2, the pressing portion FD4, and the pressing portion FD8, controlled by the processing unit 63, each press an outside surface 41bf of the second side member 41b in a direction (the right direction in the drawing) from the second side member 41b toward the first side member 41a by using the pressing values set in step S4c. In step S4e, the frame 41 becomes in a state where the first side member 41a and the second side member 41b are pressed inward.

In step S4f, the stretching unit 67, controlled by the processing unit 63, sequentially stretches the mask sheets 40 onto the frame 41. The mask sheet 40 includes active regions 40p arranged in the direction y and also includes a non-active area that surrounds the active regions. The non-active area includes two welding portions 40j between which the active regions 40p are disposed and also includes four grip regions 40c corresponding to four corners of the mask sheet 40. Note that the active region 40p corresponds to one displaying portion of the device, and a through-hole corresponding to a subpixel is formed in the active region 40p.

In FIG. 5 and FIGS. 7A to 7C, seven mask sheets 40 are sequentially stretched from the central portion toward the end portions of the frame. In other words, the first mask sheet 40 is stretched so as to overlap with the covering sheets CS3 and CS4; the second mask sheet 40 is stretched so as to overlap with the covering sheets CS2 and CS3; and the third mask sheet 40 is stretched so as to overlap with the covering sheets CS4 and CS5. Here, the mask sheet 40 is aligned while being stretched outward as indicated by the arrows by using grippers Gp for gripping a gripping region 40c. Then, one of the two welding portions 40j is welded to the first side member 41a, and the other one is welded to the second side member 41b. A method for welding includes spot welding using laser irradiation. Note that the layered body 7 in FIG. 3 is disposed on the upper face side of the mask sheet 40.

In FIGS. 7A to 7C, a combination of a pressing vector V1 of the pressing portion FD1 and a pressing vector V2 of the pressing portion FD2, a combination of a pressing vector V3 of the pressing portion FD3 and a pressing vector V4 of the pressing portion FD4, a combination of a pressing vector V5 of the pressing portion FD5 and a pressing vector V6 of the pressing portion FD6, a combination of a pressing vector V7 of the pressing portion FD7 and a pressing vector V8 of the pressing portion FD8 each have the combination of vectors, extending on the same straight line in opposite directions, that have substantially the same size (pressing values). The sizes (pressing values) may be set to be V1=V2=V3=V4=V5=V6=V7=V8, or may be set to be V1=V2=V3=V4>V5=V6=V7=V8 by considering that the distortion at the central portion of the frame tends to increase.

For example, in the case where n pieces of the mask sheets 40 are stretched and the average tension of these sheets is Tm, it may be possible to have an relationship of Tm×n≥pressing value of the pressing portion FD1+ pressing value of the pressing portion FD3+ pressing value of the pressing portion FD5+ pressing value of the pressing portion FD7. The setting value of each pressing portion ranges, for example, from 0 to 100 kgf. Each pressing portion has a contact portion with the first side member or second side member, the contact portion having, for example, a circular shape with a diameter of several tens of mm.

In FIGS. 7A to 7C, the first mask sheet 40 (that is first stretched) passes through a gap between the pressing portion FD1 and the pressing portion FD3 and a gap between the pressing portion FD2 and the pressing portion FD4 in a plan view. However, the configuration is not limited to this.

The pressing portions FD1 to FD8 press the outside surface 41af of the first side member 41a or the outside surface 41bf of the second side member 41b, and the position of pressing in the direction z (a direction perpendicular to the direction y and the direction x; the height direction of the frame) is located at the central portion of the outside surface (41af, 41bf) (see FIG. 7C). However, the configuration is not limited to this. It may be possible to press the upper portion (portion close to the mask sheet) of the outside surface (41af, 41bf).

Once all (seven pieces of) the mask sheets 40 have been stretched, the press against the frame 41 is released (step S4g), and unnecessary portions (outside of the welding portion 40j) of the mask sheet 40 is cut off (step S4h). In this way, the vapor deposition mask 50 illustrated in FIG. 5 can be obtained.

According to the first embodiment, once the (outward) stress of the frame 41 against the press of the pressing portions FD1 to FD8 is released in step S4g (release press), the (inward) tension that the frame receives from the seven mask sheets 40 is canceled out, and hence, in the vapor deposition mask 50 (FIG. 5), the deformation of the frame 41 caused by the tension of the mask sheets 40 can be prevented.

### Second Embodiment

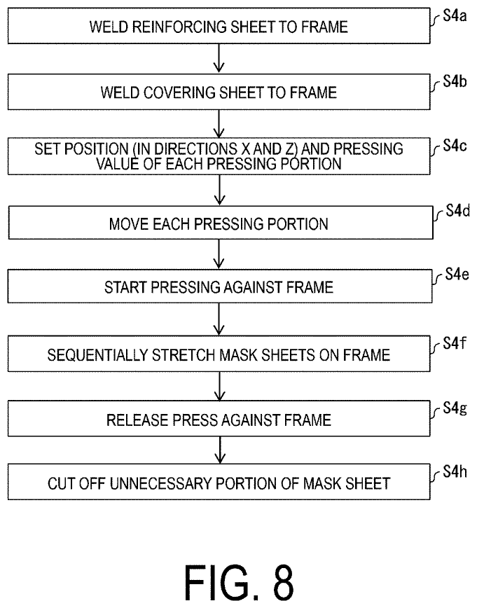

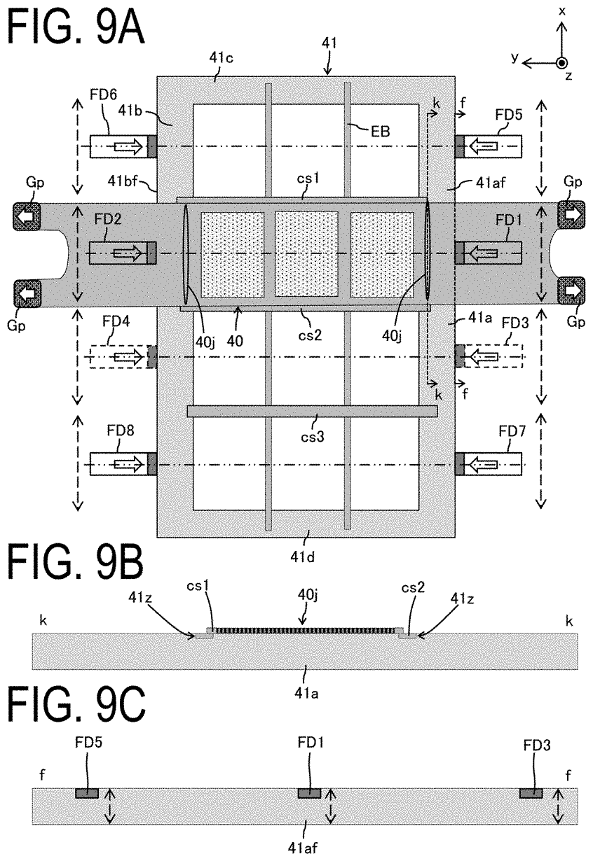

FIG. 8 is a flowchart illustrating a method for manufacturing a vapor deposition mask according to a second embodiment. FIG. 9A is a plan view, FIG. 9B is a cross-sectional view, and FIG. 9C is a side view, each illustrating a pressing mechanism according to the second embodiment.

It is desirable that the position (pressing position) of each of the pressing portions FD1 to FD8 can be set according to a size, tension, or the like of the mask sheet. In the second embodiment, the pressing portions FD1 to FD8 are configured so as to be able to move in the direction x and the direction z (the direction perpendicular to the direction x and the direction y; third direction), and the position (direction x, z) and the pressing values of the pressing portions FD1 to FD8 are set in step S4c in FIG. 8.

In step S4d, the pressing portions FD1 to FD8 that are controlled by the processing unit 63 move to positions (see FIGS. 9A to 9C) set in step S4c. In other words, the pressing portion FD5, the pressing portion FD1, the pressing portion FD3, and the pressing portion FD7 are arranged, outside the first side member 41a, in the direction x in this order from the third side member 41c side. At the positions set in step S4c, the pressing portion FD5, the pressing portion FD1, the pressing portion FD3, and the pressing portion FD7 each press the upper portion of the outside surface 41af of the first side member 41a in a direction (the left direction in the drawing) from the first side member 41a toward the second side member 41b by using the pressing values set in step S4c.

Furthermore, the pressing portion FD6, the pressing portion FD2, the pressing portion FD4, and the pressing portion FD8 are arranged, outside the second side member 41b, in the direction x in this order from the third side member 41c side. At the positions set in step S4c, the pressing portion FD6, the pressing portion FD2, the pressing portion FD4, and the pressing portion FD8 each press the upper portion of the outside surface 41bf of the second side member 41b in a direction (the right direction in the drawing) from the second side member 41b toward the first side member 41a by using the pressing values set in step S4c.

In the case of the frame 41 illustrated in FIGS. 9A to 9C, four mask sheets 40 can be stretched. In a plan view, the mask sheet 40 that is first stretched (so as to overlap with the covering sheets cs1 and cs2) overlaps with the pressing portion FD1 and the pressing portion FD2, the mask sheet 40 that is second stretched overlaps with the pressing portion FD3 and the pressing portion FD4, the mask sheet 40 that is third stretched overlaps with the pressing portion FD5 and the pressing portion FD6, and the mask sheet 40 that is fourth stretched overlaps with the pressing portion FD7 and the pressing portion FD8.

According to the second embodiment, it is possible to set the positions (pressing positions) of the pressing portions FD1 to FD8 in the direction x and the direction z according to a size, tension, or the like of the mask sheet, and hence it is possible to more effectively prevent the deformation of the frame 41.

In FIG. 8, the four mask sheets 40 are sequentially stretched with the pressing values for the pressing portions FD1 to FD8 being maintained to those set in step S4c. However, the configuration is not limited to this. For example, in FIGS. 9A to 9C, a method may be possible such that predetermined pressing values of pressing portions FD1 to FD8 are set to stretch the first mask sheet 40, then at least one of the pressing values of the pressing portions FD1 to FD8 is changed to stretch the second mask sheet 40, then at least one of the pressing values of the pressing portions FD1 to FD8 is changed to stretch the third mask sheet 40, and then at least one of the pressing values of the pressing portions FD1 to FD8 is changed to stretch the fourth mask sheet 40.

As one example, the pressing values of the pressing portions FD1 and FD2 may be decreased after the (first) mask sheet 40 is stretched (welded to the frame 41) to overlap with the covering sheets cs1 and cs2, the pressing values of the pressing portions FD3 and FD4 may be decreased after the (second) mask sheet 40 is stretched to overlap with the covering sheets cs2 and cs3, the pressing values of the pressing portions FD5 and FD6 may be decreased after the (third) mask sheet 40 is stretched to overlap with the covering sheet cs1 and the third side member 41c, and the pressing values of the pressing portions FD7 and FD8 may be decreased after the (fourth) mask sheet 40 is stretched to overlap with the covering sheet cs3 and the fourth side member 41d.

### Supplement

An electro-optical element (an electro-optical element whose luminance and transmittance are controlled by an electric current) that is provided in the display device according to the present embodiment is not particularly limited. Examples of the display device according to the present embodiment include an organic electroluminescence (EL) display provided with the Organic Light Emitting Diode (OLED) as the electro-optical element, an inorganic EL display provided with an inorganic light emitting diode as the electro-optical element, and a Quantum dot Light Emitting Diode (QLED) display provided with a QLED as the electro-optical element.

The disclosure is not limited to the embodiments stated above. Embodiments obtained by appropriately combining technical approaches stated in each of the different embodiments also fall within the scope of the technology of the disclosure. Moreover, novel technical features may be formed by combining the technical approaches stated in each of the embodiments.

### First Aspect

Provided is a method for manufacturing a vapor deposition mask including a frame including a first side member and a second side member that extend in a first direction; and one or more mask sheets, the method including: stretching the one or more mask sheets on the first side member and the second side member in a state where an outside of the first side member is pressed in a direction from the first side member toward the second side member and where an outside of the second side member is pressed in a direction from the second side member toward the first side member.

### Second Aspect

In the method for manufacturing a vapor deposition mask, for example, according to the first aspect, the outside of the first side member is pressed using a plurality of pressing portions, and the outside of the second side member is pressed using a plurality of pressing portions.

### Third Aspect

In the method for manufacturing a vapor deposition mask, for example, according to the second aspect, each of the plurality of pressing portions configured to press the outside of the first side member and the plurality of pressing portions configured to press the outside of the second side member is movable in the first direction.

### Fourth Aspect

In the method for manufacturing a vapor deposition mask, for example, according to the third aspect, the frame includes a third side member and a fourth side member that extend in a second direction perpendicular to the first direction.

### Fifth Aspect

In the method for manufacturing a vapor deposition mask, for example, according to the fourth aspect, the one or more mask sheets are welded to upper faces of the first side member and the second side member.

### Sixth Aspect

In the method for manufacturing a vapor deposition mask, for example, according to any one of the first to fifth aspects, three or more mask sheets are stretched, and a mask sheet first stretched is disposed between a mask sheet stretched second and a mask sheet stretched third.

### Seventh Aspect

In the method for manufacturing a vapor deposition mask, for example, according to the fourth aspect, each of the plurality of pressing portions configured to press the outside of the first side member and the plurality of pressing portions configured to press the outside of the second side member is movable in a third direction perpendicular to the first direction and the second direction.

### Eighth Aspect

In the method for manufacturing a vapor deposition mask, for example, according to the fifth aspect, central portions or upper portions of outside surfaces of the first side member and the second side member are pressed.

### Ninth Aspect

In the method for manufacturing a vapor deposition mask, for example, according to the second aspect, a pressing value for each of the plurality of pressing portions can be set individually.

### Tenth Aspect

In the method for manufacturing a vapor deposition mask, for example, according to the ninth aspect, the pressing value for each of the plurality of pressing portions for the first side member decreases from the center toward an end portion of the first side member, and the pressing value for each of the plurality of pressing portions for the second side member decreases from the center toward an end portion of the second side member.

### Eleventh Aspect

Provided is a device configured to manufacture a vapor deposition mask including a frame including a first side member and a second side member that extend in a first direction; and one or more mask sheets, the device being configured to stretch the one or more mask sheets on the first side member and the second side member in a state where an outside of the first side member is pressed in a direction from the first side member toward the second side member and where an outside of the second side member is pressed in a direction from the second side member toward the first side member.

### Twelfth Aspect

The device configured to manufacture a vapor deposition mask, for example, according to the eleventh aspect, includes a plurality of pressing portions configured to press the outside of the first side member and a plurality of pressing portions configured to press the outside of the second side member, in which each of the plurality of pressing portions is movable in the first direction.

### REFERENCE SIGNS LIST

2 Display device
3 Barrier layer
4 TFT layer
5 Light-emitting element layer
6 Sealing layer
12 Resin layer
16, 18, 20 Inorganic insulating film
21 Flattening film
23 Bank
24 EL layer
41 Frame
41a to 41d Side member
50 Vapor deposition mask
60 Device for manufacturing vapor deposition mask
61 Input unit
63 Processing unit
67 Stretching unit
FD1 to FD8 Pressing portion

1. A method for manufacturing a vapor deposition mask, the vapor deposition mask including a frame including a first side member and a second side member that extend in a first direction; and three or more mask sheets, the method comprising:
stretching the three or more mask sheets on the first side member and the second side member in a state where an outside of the first side member is pressed in a direction from the first side member toward the second side member and where an outside of the second side member is pressed in a direction from the second side member toward the first side member,
wherein, among the three or more mask sheets, a mask sheet stretched first is disposed between a mask sheet stretched second and a mask sheet stretched third.

2. The method for manufacturing a vapor deposition mask according to claim 1,
wherein the outside of the first side member is pressed using a plurality of pressing portions, and the outside of the second side member is pressed using a plurality of pressing portions.

3. The method for manufacturing a vapor deposition mask according to claim 2,
wherein each of the plurality of pressing portions configured to press the outside of the first side member and the plurality of pressing portions configured to press the outside of the second side member is movable in the first direction.

4. The method for manufacturing a vapor deposition mask according to claim 3,
wherein the frame includes a third side member and a fourth side member that extend in a second direction perpendicular to the first direction.

5. The method for manufacturing a vapor deposition mask according to claim 4,
wherein the three or more mask sheets are welded to upper faces of the first side member and the second side member.

6. (canceled)

7. The method for manufacturing a vapor deposition mask according to claim 4,
wherein each of the plurality of pressing portions configured to press the outside of the first side member and the plurality of pressing portions configured to press the outside of the second side member is movable in a third direction perpendicular to the first direction and the second direction.

8. The method for manufacturing a vapor deposition mask according to claim 5,
wherein central portions or upper portions of outside surfaces of the first side member and the second side member are pressed.

9. The method for manufacturing a vapor deposition mask according to claim 2,
wherein a pressing value for each of the plurality of pressing portions can be set individually.

10. The method for manufacturing a vapor deposition mask according to claim 9,
wherein the pressing value for each of the plurality of pressing portions for the first side member decreases from the center toward an end portion of the first side member, and the pressing value for each of the plurality of pressing portions for the second side member decreases from the center toward an end portion of the second side member.

11-12. (canceled)

13. A method for manufacturing a vapor deposition mask including a frame including a first side member and a second side member that extend in a first direction, and one or more mask sheets, the method comprising:
stretching the one or more mask sheets on the first side member and the second side member in a state where an outside of the first side member is pressed in a direction from the first side member toward the second side member and an outside of the second side member is pressed in a direction from the second side member toward the first side member,
wherein the outside of the first side member is pressed using a plurality of pressing portions, and the outside of the second side member is pressed using a plurality of pressing portions,
a pressing value for each of the plurality of pressing portions can be set individually, and
the pressing value for each of the plurality of pressing portions for the first side member decreases from the center toward an end portion of the first side member, and the pressing value for each of the plurality of pressing portions for the second side member decreases from the center toward an end portion of the second side member.
